(19) United States
(12) Patent Application Publication
(10) Pub. No.: US 2010/0263918 A1
(43) Pub. Date: Oct. 21, 2010

(54) LAYOUT METHOD AND CIRCUIT BOARD

(75) Inventors: Yung-Hsu LIN, Hsin-Chu (TW); Sheng-Kai Hsu, Hsin-Chu (TW); Chih-Sung Wang, Hsin-Chu (TW)

Correspondence Address: LanWay IPR Services, P.O. Box 220746, Chantilly, VA, 20153, US

(73) Assignee: LAYOUT METHOD AND CIRCUIT B

(21) Appl. No.: 12/825,422

(22) Filed: Jun. 29, 2010

Related U.S. Application Data
(62) Division of application No. 11/681,993, filed on Mar. 5, 2007, now Pat. No. 7,772,064.

(51) Int. Cl. H05K 1/00; G06F 17/50; H05K 1/11

(52) U.S. Cl. 174/254; 716/15; 174/261

(57) ABSTRACT

A circuit board and a layout method therefor are provided. The circuit board is adapted for coupling between two circuits and includes multiple first pins, multiple second pins, a chip-disposing area for disposing a circuit chip, and a routing area including electrical routes. The first pins are coupled to one the circuit, and the second pins are coupled to the other one circuit. Two terminals of each of a first group of electrical routes of the electrical routes respectively are coupled to one of the first pins and the chip-disposing area, and two terminals of each of a second group of electrical routes of the electrical routes respectively are coupled to the chip-disposing area and one of the second pins. The second group of electrical routes and at least one of the first pins therebetween do not have any one of the first group of electrical routes.

### CROSS-REFERENCE TO RELATED APPLICATIONS

This application is based upon and claims the benefit of priority from the prior Taiwan Patent Application No. 098136582, filed Oct. 28, 2009, the entire contents of which are incorporated herein by reference.

### BACKGROUND

1. Technical Field

The present invention generally relates to printed circuit boards (PCBs) and, particularly to a layout method and a circuit board, which can make full use of a space of circuit board for wire routing.

2. Description of the Related Art

Referring to FIG. 6, a schematic view of wire routing for a conventional circuit board is shown. In the prior art, the circuit board 600 is electrically coupled between a controller circuit (not shown) and a display area circuit (not shown). The circuit board 600 includes first pins 602, second pins 604, a chip-disposing area 606 and a routing area 608.

The first pins 602 are electrically coupled to the controller circuit. The second pins 604 are electrically coupled to the display area circuit. The chip-disposing area 606 is configured for disposing a circuit chip (not shown).

The routing area 608 includes a first group of electrical routes 610, a second group of electrical routes 612 and 614, and a third group of electrical routes 616 formed therein. The first group of electrical routes 610 are electrically coupled to the first pins 602 and the chip-disposing area 606, and the second group of electrical routes 612 and 614 are electrically coupled to the second pins 604 and the chip-disposing area 606. The third group of electrical routes 616 are electrically coupled to the first pins 602 and the second pins 604.

In the prior art, since a part of the first pins 602 are configured for testing whether a driver chip can normally operate or not after the driver chip is disposed on the chip-disposing area 606, therefore the first group of electrical routes 610 include electrical routes for testing the driver chip. In FIG. 6, since the first pins 602 are electrically coupled to all the first group of electrical routes 610 for the chip-disposing area 606, therefore the second group of electrical routes 612 and 614 are disposed below the first group of electrical routes 610. However, nowadays, with the progressively increase of the pin amount of the driver chip, such conventional design of circuit board inevitably results in the wire routing being unable to be completed on the limited space of the circuit board 600.

### BRIEF SUMMARY

Accordingly, the present invention relates to a layout method, which can increase the size of a routing area without increasing an area of circuit board.

The present invention further relates to a circuit board having a relatively smaller area of circuit board.

The present invention still further relates to a layout method, which can widen a width of a power supply route for enlarging a heat-dissipating area of the power supply route.

The present invention even still further relates to a circuit board having a relatively smaller area of circuit board by employing a scheme of single-side wire routing.

More specifically, a layout method in accordance with an exemplary embodiment of the present invention is adapted for a circuit board. The circuit board is adapted to being electrically coupled between two circuits. The layout method includes the following steps of: (1) providing a plurality of first pins on the circuit board and adapted for electrically coupling to one of the two circuits; (2) providing a plurality of second pins on the circuit board and adapted for electrically coupling to another one of the two circuits; (3) providing a chip-disposing area on the circuit board and adapted for disposing a circuit chip; and (4) providing a routing area on the circuit board, wherein the routing area includes a plurality of electrical routes disposed therein. Two terminals of each of a first group of electrical routes of the electrical routes are respectively electrically coupled to one of the first pins and the chip-disposing area, and two terminals of each of a second group of electrical routes of the electrical routes respectively are electrically coupled to the chip-disposing area and one of the second pins. The second group of electrical routes and at least one of the first pins do not have any one of the first group of electrical routes disposed just therebetween.

In an exemplary embodiment of the present invention, two terminals of a third group of electrical routes of the electrical routes respectively are electrically coupled to one of the first pins and one of the second pins.

In an exemplary embodiment of the present invention, the first group of electrical routes are disposed between the first pins and a first side of the chip-disposing area.

In an exemplary embodiment of the present invention, at least one of the second group of electrical routes is disposed between two of the first pins.

A circuit board in accordance with another exemplary embodiment of the present invention is adapted to being electrically coupled between two circuits. The circuit board includes a plurality of first pins, a plurality of second pins, a chip-disposing area and a routing area. The first pins are adapted to being electrically coupled to one of the two circuits, and the second pins are adapted to being electrically coupled to another one of the two circuits. The chip-disposing area is configured (i.e., structured and arranged) for disposing a circuit chip, and the routing area including a plurality of electrical routes disposed therein. Two terminals of each of a first group of electrical routes of the electrical routes respectively are electrically coupled to one of the first pins and the chip-disposing area, and two terminals of each of a second group of electrical routes of the electrical routes respectively are electrically coupled to the chip-disposing area and one of the second pins. The second group of electrical routes and at least one of the first pins do not have any one of the first group of electrical routes disposed just thereteween.

A layout method in accordance with still another exemplary embodiment of the present invention is adapted for a circuit board. The circuit board is adapted to being electrically coupled between two circuits. The layout method includes the following steps of: (1) providing a plurality of first pins on the circuit board and adapted for electrically coupling to one of the two circuits; (2) providing a plurality of second pins on the circuit board and adapted for electrically coupling to another one of the two circuits; (3) providing a chip-disposing area on the circuit board and adapted for disposing a circuit chip; and (4) providing a routing area on the circuit board, wherein the routing area includes a plurality of electrical routes disposed therein. Two terminals of each of a first group of electrical routes of the electrical routes respectively are electrically coupled to one of the first pins and a first side of the chip-disposing area, and two terminals of each of a second group of electrical routes of the electrical routes respectively are electrically coupled to a second side of the chip-disposing area and one of the second pins. A width of at least a power supply route of the first group of electrical routes, with respect to the other electrical routes of the first group of electrical routes, is widened to enlarge a heat-dissipating area of the power supply route.

A circuit board in accordance with even still another exemplary embodiment of the present invention is adapted to being electrically coupled to two circuits. The circuit board includes a plurality of first pins, a plurality of second pins, a chip-disposing area and a routing area. The first pins are adapted to being electrically coupled to one of the two circuits, and the second pins are adapted to being electrically coupled to another one of the two circuits. The chip-disposing area is configured for disposing a circuit chip, and the routing area including a plurality of electrical routes disposed therein. Two terminals of each of a first group of electrical routes of the electrical routes respectively are electrically coupled to one of the first pins and a first side of the chip-disposing area, and two terminals of each of a second group of electrical routes of the electrical routes respectively are electrically coupled to a second side of the chip-disposing area and one of the second pins. A width of at least a power supply route of the first group of electrical routes, with respect to the other electrical routes of the first group of electrical routes, is widened to enlarge a heat-dissipating area of the power supply route.

In summary, in the embodiments of the present invention, the second group of electrical routes and at least one of the first pins do not have any one of the first group of electrical routes disposed therebetween, therefore the area occupied by the first group of electrical routes can be saved/reduced, and the saved area can be utilized by the second group of electrical routes, so that the space of circuit board can be effectively utilized. Moreover, since the power supply route(s) in the first group of electrical routes is/are widen compared with the prior art, an area of heat-dissipating for the power supply route(s) can be increased.

### BRIEF DESCRIPTION OF THE DRAWINGS

These and other features and advantages of the various embodiments disclosed herein will be better understood with respect to the following description and drawings, in which like numbers refer to like parts throughout, and in which:

FIG. 1 is a schematic view of wire routing for a circuit board in accordance with an exemplary embodiment of the present invention.

FIG. 2 is a schematic view of wire routing for a circuit board in accordance with another exemplary embodiment of the present invention.

FIG. 3 is a flow chart of a layout method in accordance with an exemplary embodiment of the present invention.

FIG. 4 is a schematic view of wire routing for a circuit board in accordance with still another exemplary embodiment of the present invention.

FIG. 5 is a flow chart of a layout method in accordance with another exemplary embodiment of the present invention.

FIG. 6 is a schematic view of wire routing for a conventional circuit board.

### DETAILED DESCRIPTION

Reference will now be made to the drawings to describe exemplary embodiments of the present layout method and the present circuit board in detail. The following description is given by way of example, and not limitation.

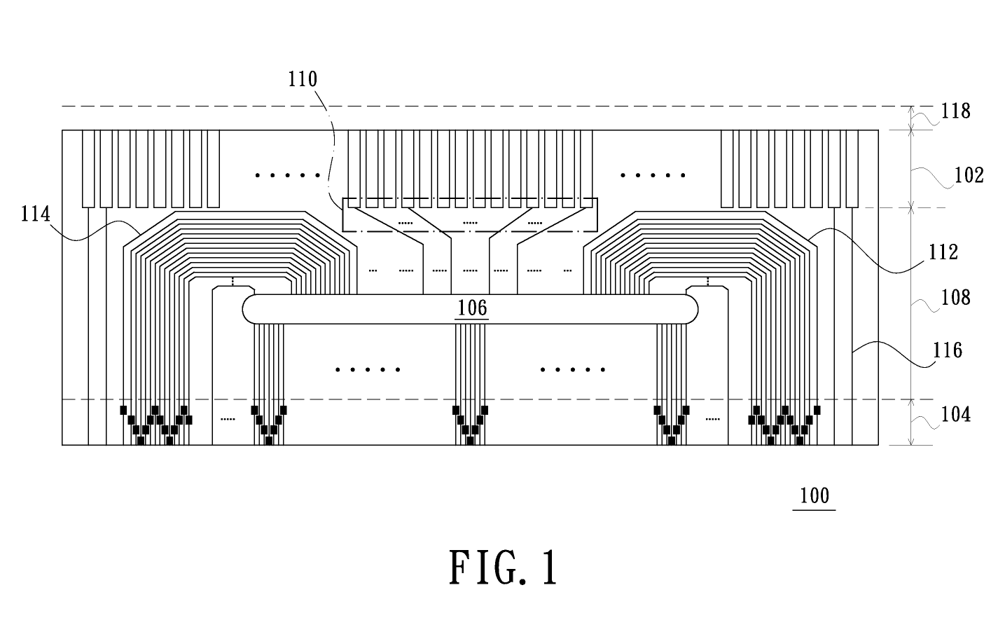

Referring to FIG. 1, a schematic view of wire routing for a circuit board in accordance with an exemplary embodiment of the present invention is shown. The circuit board 100 is adapted to being electrically coupled between two circuits (not shown). The circuit board 100 includes a plurality of first pins 102, a plurality of second pins 104, a chip-disposing area 106 and a routing area 108. It is understood to the skilled person in the art that the two circuits respectively may be a printed circuit board and a display area circuit of a display device, but is not to limit the present invention.

In this exemplary embodiment, the first pins 102 are electrically coupled to one of the two circuits. The first pins 102 are for example pads. The second pins 104 are electrically coupled to another one of the two circuits. The second pins 104 are for example configured for testing whether the circuit board 100 can normally operate or not, and therefore the second pins 104 generally are trimmed off after the circuit board 100 is assembled.

The chip-disposing area 106 is configured for disposing a circuit chip. It is understood to the skilled person in the art that the circuit chip is for example a scan-line driver chip or a data-line driver chip of the display device.

The routing area 108 includes a first group of electrical routes 110, second group of electrical routes 112 and 114, and a third group of electrical routes 116. A terminal of each of the first group of electrical routes 110 is electrically coupled to one of a part of the first pins 102 and for receiving signals (such as control signals or timing signals) transmitted from the printed circuit board on which a controller is located. Another terminal of each of the first group of electrical routes 110 is electrically coupled to the chip-disposing area 106 and for transmitting the signals to the chip-disposing area 106. A terminal of each of the second group of electrical routes 112 and 114 is electrically coupled to the chip-disposing area 106, and another terminal thereof is electrically coupled to one of the second pins 104. The second group of electrical routes 112 and 114 are configured for transmitting scan signals and/or data signals outputted from the driver chip to the display area circuit. A terminal of the third group of electrical routes 116 is electrically coupled to one of another part of the first pins 102, and another terminal thereof is electrically coupled to one of the second pins 104 and for transmitting the signals outputted from the controller (not shown) are transmitted to the display area circuit through the third group of electrical routes 116.

Since the scan lines and the data lines of the display device are progressively increased, in order to achieve the purpose of effective utilization of the space on the circuit board 100, electrical routes being of the first group of electrical routes 110 and originally/conventionally used for testing the driver chip or unused are cancelled/omitted. That is, the second group of electrical routes 112, 114 and at least one of the first pins 102 do not have any one of the first group of electrical routes 110 disposed just therebetween. Therefore, the space occupied by the first group of electrical routes 110 is decreased, and the saved space can be used for layout of the second group of electrical routes 112 and 114.

In a preferred exemplary embodiment of the present invention, the area of the circuit board 100 can be designed to be smaller than that of the conventional circuit board, and a saved vertical size of the circuit board 100 (that is, a longitudinal width of the saved area 118 as shown in FIG. 1) is slightly smaller than a distance between an upper edge of the second group of electrical routes 612, 614 and a lower edge of the first pins 602.

In a preferred exemplary embodiment of the present invention, the first group of electrical routes 110 are disposed between the first pins 102 and a first/upper side of the chip-disposing area 106.

In a preferred exemplary embodiment of the present invention, the chip-disposing area 106 may be a socket of a driver chip or a plurality of through holes on the circuit board 100 configured for containing/receiving a driver chip.

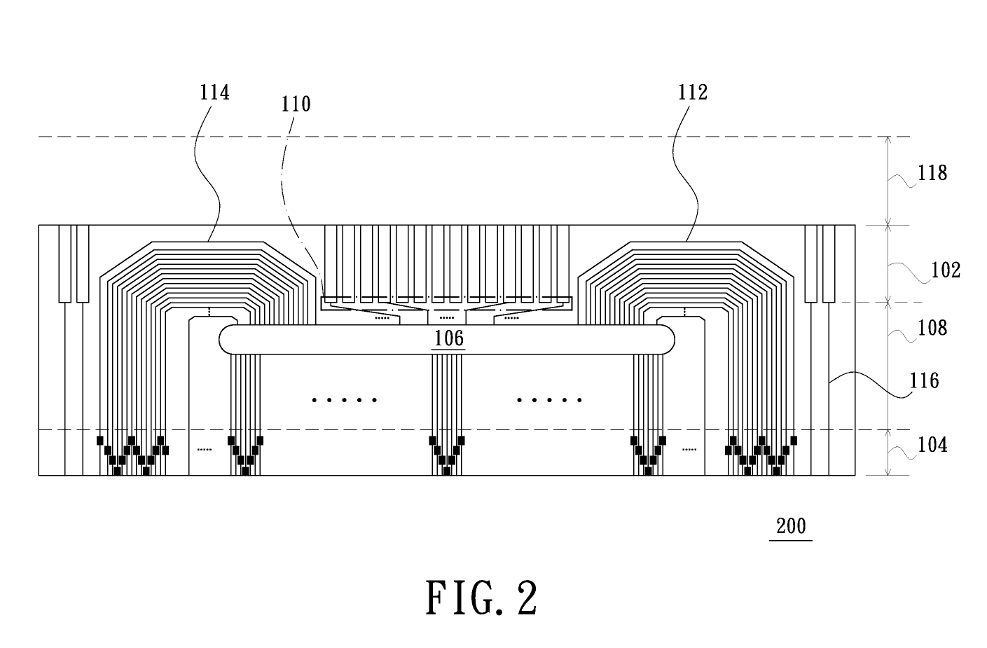

Referring to FIG. 2, a schematic view of wire routing for a circuit board in accordance with another exemplary embodiment of the present invention is shown. For the convenience of description, elements of FIG. 2 same or like to those of FIG. 1 are indicated by the same labels, and the content associated with same functions will not be described below.

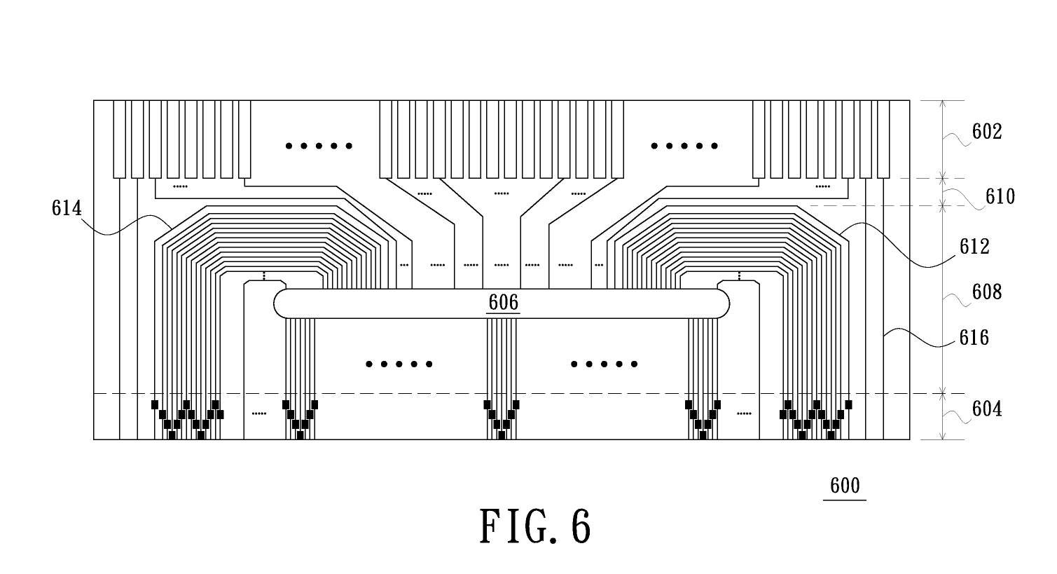

In this exemplary embodiment, the circuit board of FIG. 2 is similar to that of FIG. 1 except that the circuit board 100 of FIG. 2 cancels/removes the part of the first pins 102 which are originally/conventionally for testing the driver chip or unused, i.e, the circuit board 100 of FIG. 2 only retains some of the first pins 102 which are necessarily used after completing/finishing the assembly of the circuit board 100. Such scheme/design would create an unused area formed between two of the first pins 102, and therefore the second group of electrical routes 112 and 114 can be disposed in the unused area by the designer for fully utilizing the space of circuit board. A longitudinal width of a saved area 118 obtained by use of the configuration as shown in FIG. 2 is slightly smaller than the sum of vertical longitudinal width for disposing the first pins 602 and another longitudinal width of the first group of electrical routes 610 as shown in FIG. 6.

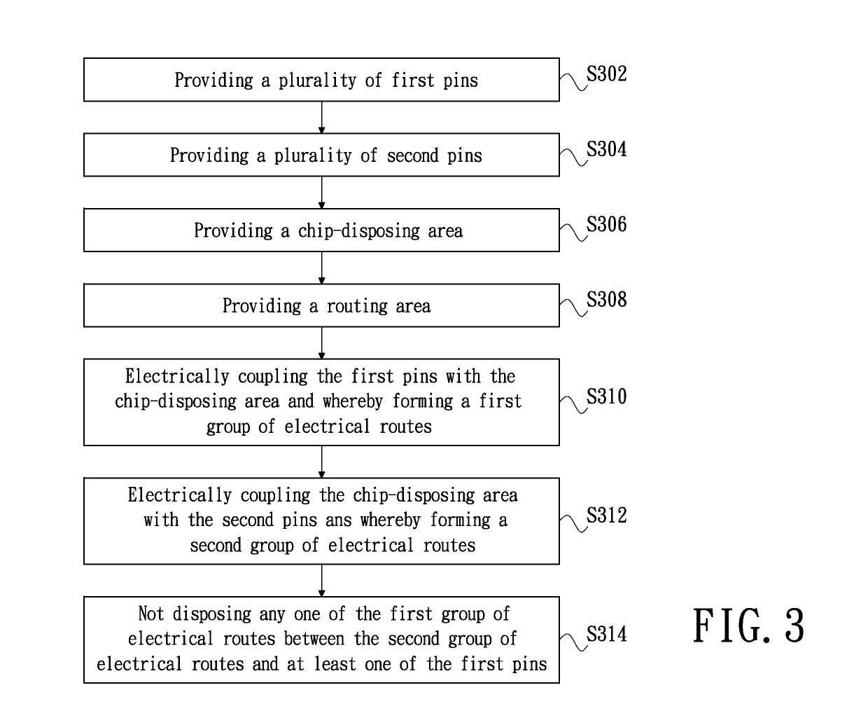

Hereinafter, referring to FIG. 3, a flow chart of a layout method in accordance with an exemplary embodiment of the present invention is shown. The layout method is adapted for each of the circuit boards 100 as shown in FIGS. 1 and 2. Referring to FIGS. 1 and 3 together, in this exemplary embodiment, the layout method firstly provides a plurality of first pins 102 on the circuit board 100 and adapted to being electrically coupled to the circuit board having a controller (Step S302). Then, the layout method provides a plurality of second pins 104 on the circuit board 100 and adapted to being electrically coupled to a display area circuit (Step S304).

Subsequently, a chip-disposing area 106 is provided on the circuit board 100 to contain/receive and fix a driver chip, so as to electrically couple with the driver chip (Step S306). Afterwards, a routing area 108 is provided on the circuit board 100 to dispose a plurality of electrical routes (Step S308).

After performing the step S308, the first pins 102 are electrically coupled to the chip-disposing area 106 so as to form a first group of electrical routes 110 (Step S310). Then, the second pins 104 are electrically coupled to the chip-disposing area 106 so as to form a second group of electrical routes 112 and 114 (Step S312). Furthermore, any one of the first group of electrical routes 110 is not disposed between the second part electrical routes 112, 114 and at least one of the first pins 102 (Step S314), in other words, the second group of electrical routes 112, 114 and at least one of the fin pins 102 do not have any one of the first group of electrical routes 110 disposed just therebetween.

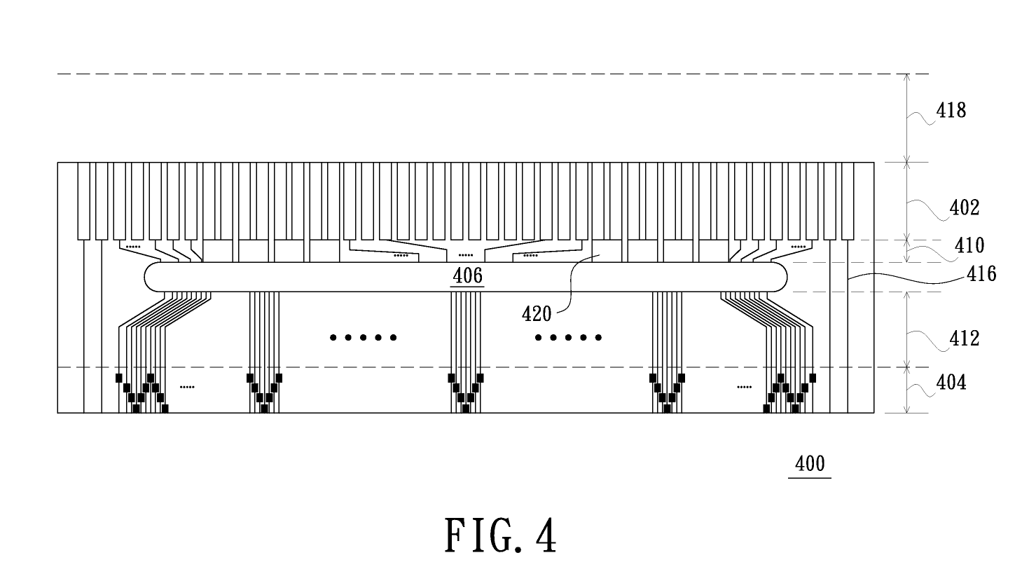

Referring to FIG. 4, a schematic view of wire routing for a circuit board in accordance with still another exemplary embodiment of the present invention is shown. The circuit board 400 is adapted to being electrically coupled between two circuits. The circuit board 400 includes a plurality of first pins 402, a plurality of second pins 404 and a chip-disposing area 406. It is understood to the skilled person in the art that the two circuits respectively may be a printed circuit board (PCB) and a display area circuit of a display device, but the present invention is not limited to this.

In this exemplary embodiment, the first pins 402 are adapted to being electrically coupled to one of the two circuits. The first pins 402 may be pads. The second pins 404 are adapted to being electrically coupled to another one of the two circuits. The second pins 404 may be pins configured for testing whether the circuit board 400 can normally operate or not. Generally, after the circuit board 400 is assembled, the second pins 404 are trimmed off.

The chip-disposing area 406 is configured for disposing a circuit chip. It is understood to the skilled person in the art that the circuit chip may be a scan-line driver chip or a data-line driver chip of the display device.

In this exemplary embodiment, the circuit board 400 employs a single-side wire routing solution, thus a first group of electrical routes 410 are formed between the first pins 402 and the chip-disposing area 406, a second group of electrical routes 412 are formed between the chip-disposing area 406 and the second pins 404, and a third group of electrical routes 416 are formed between the first pins 402 and the second pins 404. In particular, a terminal of each of the first group of electrical routes 410 is electrically coupled to one of a part of the first pins 402 and for receiving signals (such as control signals or timing signals) transmitted from a printed circuit board having a controller formed thereon, another terminal of each of the first group of electrical routes 410 is electrically coupled to the chip-disposing area 406 for transmitting the signals to the chip-disposing area 406. A terminal of each of the second group of electrical routes 412 and 414 is electrically coupled to the chip-disposing area 406, and another terminal thereof is electrically coupled to one of the second pins 404. The second group of electrical routes 412 and 414 are configured for outputting scan signals and/or data signals outputted from the driver chip to the display area circuit. A terminal of each of the third group of electrical route s416 is electrically coupled to one of another part of the first pins 402, and another terminal thereof is electrically coupled to one of the second pins 404, such that signals outputted from a controller (not shown) are transmitted to the display area circuit through the third group of electrical routes 416.

The first group of electrical routes 410 include a plurality of power supply routes 420. For improving the heat-dissipating efficiency of the power supply routes 420, the widths of the power supply routes 420 are widened to enlarge the heat-dissipating areas of the power supply routes 420, for example as illustrated in FIG. 4, the width of each of the power supply routes 420 is larger than that of the other electrical routes of the first group of electrical routes 410. Therefore, the power supply routes 420 will be not burned down or failed caused by excessive heat.

In a preferred exemplary embodiment of the present invention, the area of the circuit board 400 can be designed to be smaller than that of the conventional circuit board and thereby a saved area is produced. A longitudinal width of the saved area 418 is substantially equal to a distance between an upper edge of the chip-disposing area 606 and an upper edge of the second group of electrical routes 612 and 614 as shown in FIG. 6.

In a preferred exemplary embodiment, the chip-disposing area 406 may be a socket of a driver chip or a plurality of through holes on the circuit board 400 for containing/receiving a driver chip.

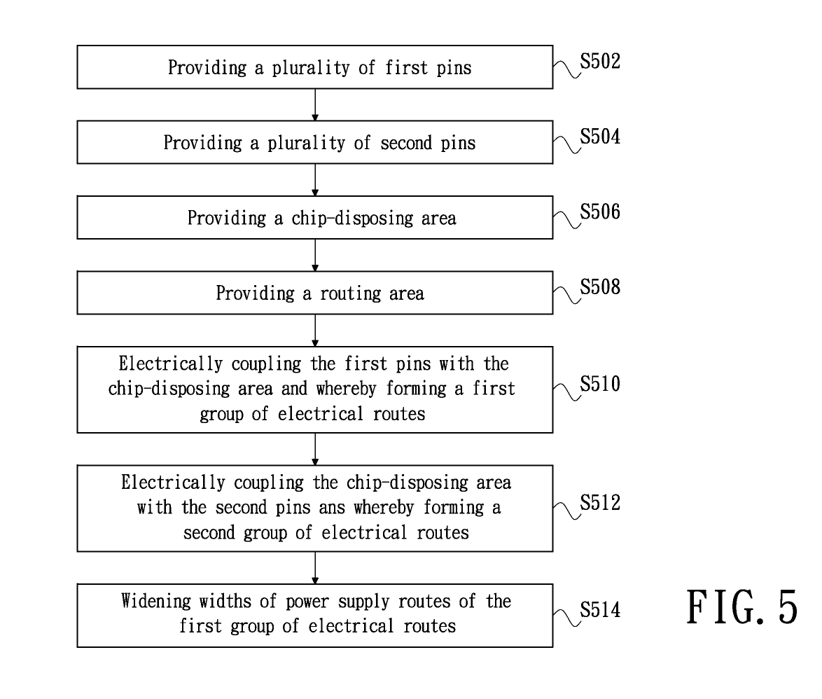

Referring to FIG. 5, a flow chat of a layout method in accordance with another exemplary embodiment of the present invention is shown. The layout method may be adapted for the circuit board 400 as shown in FIG. 4. Referring to FIGS. 4 and 5 together, in this exemplary embodiment, the layout method firstly provides a plurality of first pins 402 on the circuit board 400 and adapted to being electrically coupled to a circuit board having a controller (Step S502). Then, the layout method provides a plurality of second pins 404 on the circuit board 400 and adapted to being electrically coupled to a display area circuit (Step S504).

Subsequently, a chip-disposing area 406 is provided on the circuit board 400 to contain and fix a driver chip, so as to electrically couple with the driver chip (Step S506). Afterwards, a routing area 408 is provided on the circuit board 400 to dispose a plurality of electrical routes (Step S508).

After performing the step S508, the first pins 402 are electrically coupled to the chip-disposing area 406 to form a first group of electrical routes 410 (Step S510). Then, the second pins 404 are electrically coupled to the chip-disposing area 406 to form a second group of electrical routes 412 (Step S512). Widths of the power supply routes 420 of the first group of electrical routes 410 are widened to enlarge a heat-dissipating area of the power supply routes 420 (Step S514).

In a preferred exemplary embodiment of the present invention, the circuit board 100 and 400 may be a flexible printed circuit board.

In a preferred exemplary embodiment of the present invention, the driver chip is disposed on the chip-disposing area 106 and 406 after being tested to be without any fault.

In summary, the circuit board and the layout method in accordance with the above-mentioned embodiments of the present invention are carried out that the second group of electrical routes and at least one of the first pins do not have any one of the first group of electrical routes disposed therebetween, therefore the area occupied by the first group of electrical routes can be saved/reduced and the saved area can be utilized by the second group of electrical routes, so that the space of circuit board can be effectively utilized. Moreover, since the power supply route(s) in the first group of electrical routes is/are widen compared with the prior art, an area of heat-dissipating for the power supply route(s) can be increased.

The above description is given by way of example, and not limitation. Given the above disclosure, one skilled in the art could devise variations that are within the scope and spirit of the invention disclosed herein, including configurations ways of the recessed portions and materials and/or designs of the attaching structures. Further, the various features of the embodiments disclosed herein can be used alone, or in varying combinations with each other and are not intended to be limited to the specific combination described herein. Thus, the scope of the claims is not to be limited by the illustrated embodiments.

What is claimed is:

1. A layout method adapted for a circuit board, wherein the circuit board is electrically coupled between two circuits, the layout method comprising:
providing a plurality of first pins on the circuit board and adapted for electrically coupling to one of the two circuits;
providing a plurality of second pins on the circuit board and adapted for electrically coupling to another one of the two circuits;
providing a chip-disposing area on the circuit board and adapted for disposing a circuit chip; and
providing a routing area on the circuit board, the routing area comprising a plurality of electrical routes disposed therein;
wherein two terminals of each of a first group of electrical routes of the electrical routes respectively are electrically coupled to the chip-disposing area and one of the first pins, two terminals of each of a second group of electrical routes of the electrical routes respectively are electrically coupled to the chip-disposing area and one of the second pins, and
wherein the second group of electrical routes and at least one of the first pins do not have any one of the first group of electrical routes disposed therebetween.

2. The layout method as claimed in claim 1, wherein two terminals of each of a third group of electrical routes of the electrical routes respectively are electrically coupled to one of the first pins and one of the second pins.

3. The layout method as claimed in claim 1, wherein the first group of electrical routes are disposed between the first pins and a first side of the chip-disposing area.

4. The layout method as claimed in claim 1, wherein at least one of the second group of electrical routes is disposed between two of the first pins.

5. A circuit board, configured for being electrically coupled between two circuits, the circuit board comprising:
a plurality of first pins, configured for being electrically coupled to one of the two circuits;
a plurality of second pins, configured for being electrically coupled to another one of the two circuits;
a chip-disposing area, configured for disposing a circuit chip; and
a routing area, comprising a plurality of electrical routes disposed therein;
wherein two terminals of each of a first group of electrical routes of the electrical routes respectively are electrically coupled to the chip-disposing area and one of the first pins, two terminals of each of a second group of electrical routes of the electrical routes respectively are electrically coupled to the chip-disposing area and one of the second pins, and
wherein the second group of electrical routes and at least one of the first pins do not have any one of the first group of electrical routes disposed therebetween.

6. The circuit board as claimed in claim 5, wherein two terminals of each of a third group of electrical routes of the electrical routes respectively are electrically coupled to one of the first pins and one of the second pins.

7. The circuit board as claimed in claim 5, wherein the first group of electrical routes are disposed between the first pins and a first side of the chip-disposing area.

8. The circuit board as claimed in claim 5, wherein at least one of the second group of electrical routes is disposed between two of the first pins.

9. The circuit board as claimed in claim 5, wherein the circuit board is a flexible printed circuit board.

10. A layout method adapted for a circuit board, wherein the circuit board is electrically coupled between two circuits, the layout method comprising:
providing a plurality of first pins on the circuit board and adapted for electrically coupling to one of the two circuits;
providing a plurality of second pins on the circuit board and adapted for electrically coupling to another one of the two circuits;
providing a chip-disposing area on the circuit board and adapted for disposing a circuit chip; and
providing a routing area on the circuit board, the routing area comprising a plurality of electrical routes disposed therein;
wherein two terminals of each of a first group of electrical routes of the electrical routes respectively are electrically coupled to one of the first pins and a first side of the chip-disposing area, two terminals of each of a second group of electrical routes of the electrical routes respectively are electrically coupled to a second side of the chip-disposing area and one of the second pins, and a width of at least a power supply route of the first group of electrical routes, with respect to the other electrical routes of the first group of electrical routes, is widened for enlarging a heat-dissipating area of the power supply route.

11. The layout method as claimed in claim 10, wherein two terminals of each of a third group of electrical routes of the electrical routes respectively are electrically coupled to one of the first pins and one of the second pins.

12. A circuit board configured for being electrically coupled between two circuits, the circuit board comprising:
a plurality of first pins, configured for being electrically coupled to one of the two circuits;
a plurality of second pins, configured for being electrically coupled to another of the two circuits;
a chip-disposing area, configured for disposing a circuit chip; and
a routing area, comprising a plurality of electrical routes disposed therein;
wherein two terminals of each of a first group of electrical routes of the electrical routes respectively are electrically coupled to one of the first pins and a first side of the chip-disposing area, two terminals of each of a second group of electrical routes of the electrical routes respectively are electrically coupled to a second side of the chip-disposing area and one of the second pins, and a width of at least a power supply route of the first group of electrical routes, with respect to the other electrical routes of the first group of electrical routes, is widened for enlarging a heat-dissipating area of the power supply route.

13. The circuit board as claimed in claim 12, wherein two terminals of each of a third group of electrical routes of the electrical routes respectively are electrically coupled to one of the first pins and one of the second pins.

14. The circuit board as claimed in claim 12, wherein the circuit board is a flexible printed circuit board.
